(19) United States
(12) Patent Application Publication
(10) Pub. No.: US 2026/0293727 A1
(43) Pub. Date: Sep. 24, 2026

(54) SEMICONDUCTOR DEVICE

(71) Applicant: DENSO CORPORATION, Kariya-city (JP)

(72) Inventors: Kenta NISHIGAITO, Kariya-shi (JP); Tomomi OKUMURA, Kariya-shi (JP)

(21) Appl. No.: 19/549,455

(22) Filed: Feb. 25, 2026

(30) Foreign Application Priority Data
Mar. 18, 2025 (JP) 2025-043967

(51) Int. Cl. H10W 70/652; H10W 72/30; H10W 90/00; H10W 90/10; H10W 74/10

(52) U.S. Cl. CPC H10W 70/652; H10W 72/381; H10W 90/10; H10W 90/401; H10W 90/734; H10W 72/347; H10W 74/114

(57) ABSTRACT

A semiconductor device includes first and second substrates, first and second semiconductor elements, a joint portion, at least one spacer and a sealing body. The first and second substrates each have an insulating base material, and front and back surface metal bodies. The first and second semiconductor elements and the joint portion are electrically connected to the front surface metal bodies of the first and second substrates. The spacer is disposed between at least one of the first and second semiconductor elements and the front surface metal body of the second substrate. The insulating base material of at least one of the first and second substrates has an exposed surface exposed from the front surface metal body at a position between the spacer and the joint portion in a lateral direction and in close contact with the sealing body. The joint portion is more easily deformable than the spacer.

### CROSS REFERENCE TO RELATED APPLICATION

The present application claims the benefit of priority from Japanese Patent Application No. 2025-043967 filed on Mar 18, 2025, the entire contents of which are incorporated herein by reference.

### TECHNICAL FIELD

The present disclosure relates to a semiconductor device.

### BACKGROUND

As a related art, there is a semiconductor device having semiconductor elements, substrates, a joint portion, and a sealing body. The semiconductor elements include a semiconductor element corresponding to an upper arm and a semiconductor element corresponding to a lower arm. The semiconductor element has a drain electrode on a first end surface in a thickness direction as a main electrode. The semiconductor element has a source electrode on a second end surface in the thickness direction as a main electrode. The substrates include a substrate facing the drain electrode and a substrate facing the source electrode. The substrate has an insulating base material, a front surface metal body disposed on a front surface of the insulating base material and connected to the main electrode, and a back surface metal body disposed on a back surface of the insulating base material. The joint portion electrically connects the front surface metal body of the substrate on the drain electrode side and the front surface metal body of the substrate on the source electrode side.

### SUMMARY

According to an aspect of the present disclosure, a semiconductor device includes a first substrate, a second substrate, a semiconductor element, a joint portion, at least one spacer and a sealing body. The first substrate faces the second substrate. Each of the first substrate and the second substrate has an insulating base material, a front surface metal body disposed on a front surface of the insulating base material, and a back surface metal body disposed on a back surface of the insulating base material. The semiconductor element includes a first semiconductor element and a second semiconductor element. The first semiconductor element and the second semiconductor element are arranged along a lateral direction, and each of the first semiconductor element and the second semiconductor element is electrically connected to the front surface metal body of the first substrate and to the front surface metal body of the second substrate. The joint portion electrically connects the front surface metal body of the first substrate and the front surface metal body of the second substrate. The at least one spacer is disposed between at least one of the first semiconductor element or the second semiconductor element and the second substrate in a thickness direction of the at least one of the first semiconductor element or the second semiconductor element. The at least one spacer provides a current conduction path between the at least one of the first semiconductor element or the second semiconductor element and the front surface metal body of the second substrate. The sealing body seals the first substrate, the second substrate, the first semiconductor element, the second semiconductor element, the joint portion, and the at least one spacer. The insulating base material of at least one of the first substrate or the second substrate has an exposed surface that is exposed from the front surface metal body of the at least one of the first substrate or the second substrate at a position between the at least one spacer and the joint portion in the lateral direction and is in contact with the sealing body. The joint portion may be configured to be more easily deformable than the at least one spacer.

### BRIEF DESCRIPTION OF DRAWINGS

Objects, features and advantages of the present disclosure will become more apparent from the following detailed description made with reference to the accompanying drawings, in which:

FIG. 1 is a diagram showing a power conversion circuit and a drive system to which a semiconductor device according to a first embodiment is applied;

FIG. 2 is a perspective view of the semiconductor device;

FIG. 3 is a three-dimensional cross-sectional view of the semiconductor device;

FIG. 4 is a cross-sectional view of the semiconductor device;

FIG. 5 is a plan view of a substrate on a drain electrode side;

FIG. 6 is a plan view of a substrate on a source electrode side;

FIG. 7 is an enlarged cross-sectional view of a region VII in FIG. 4;

FIG. 8 is a stress-strain diagram of a joint portion and a spacer;

FIG. 9 is a cross-sectional view of a semiconductor device according to a second embodiment;

FIG. 10 is a cross-sectional view of a semiconductor device according to a third embodiment;

FIG. 11 is a cross-sectional view of a semiconductor device according to a fourth embodiment;

FIG. 12 is a cross-sectional view of a semiconductor device according to a fifth embodiment;

FIG. 13 is a cross-sectional view of a semiconductor device according to a sixth embodiment;

FIG. 14 is a cross-sectional view of a semiconductor device according to a seventh embodiment;

FIG. 15 is a cross-sectional view of a semiconductor device according to an eighth embodiment; and

FIG. 16 is a cross-sectional view of a semiconductor device according to a ninth embodiment.

### DETAILED DESCRIPTION

In a semiconductor device of a related art, in a substrate facing a source electrode of a semiconductor element, a part of an insulating base material on a source electrode side is exposed from a front surface metal body. For example, the insulating base material on the source electrode side is exposed between the front surface metal body connected to a semiconductor element of an upper arm and the front surface metal body connected to a semiconductor element of a lower arm, and is in close contact with a resin sealing body. The sealing body shrinks toward a package center due to curing shrinkage. At that time, if the joint portion is hard and difficult to deform, the joint becomes stiff during curing shrinkage. As a result, there is a possibility that stress concentrates on a triple junction where the insulating base material, the front surface metal body, and the sealing body overlap.

The present disclosure provides a semiconductor device in which concentration of stress on a triple junction where an insulating base material, a front surface metal body, and a sealing resin overlap is suppressed.

According to an aspect of the present disclosure, a semiconductor device includes a first substrate, a second substrate, a semiconductor element, a joint portion, at least one spacer and a sealing body. The first substrate faces the second substrate. Each of the first substrate and the second substrate has an insulating base material, a front surface metal body disposed on a front surface of the insulating base material, and a back surface metal body disposed on a back surface of the insulating base material. The semiconductor element includes a first semiconductor element and a second semiconductor element. The first semiconductor element and the second semiconductor element are arranged along a lateral direction, and each of the first semiconductor element and the second semiconductor element is electrically connected to the front surface metal body of the first substrate and to the front surface metal body of the second substrate. The joint portion electrically connects the front surface metal body of the first substrate and the front surface metal body of the second substrate. The at least one spacer is disposed between at least one of the first semiconductor element or the second semiconductor element and the second substrate in a thickness direction of the at least one of the first semiconductor element or the second semiconductor element. The at least one spacer provides a current conduction path between the at least one of the first semiconductor element or the second semiconductor element and the front surface metal body of the second substrate. The sealing body seals the first substrate, the second substrate, the first semiconductor element, the second semiconductor element, the joint portion, and the at least one spacer. The insulating base material of at least one of the first substrate or the second substrate has an exposed surface that is exposed from the front surface metal body of the at least one of the first substrate or the second substrate at a position between the at least one spacer and the joint portion in the lateral direction and is in contact with the sealing body. The joint portion is configured to be more easily deformable than the at least one spacer.

In such a configuration, when the sealing body shrinks, the joint portion is suppressed from strutting between the first substrate and the second substrate. It is less likely that stress will concentrate on a triple junction where the insulating base material, the front surface metal body, and the sealing body overlap, that is, meet together.

Hereinafter, multiple embodiments of the present disclosure will be described with reference to the drawings. In the respective embodiments, parts corresponding to each other may be denoted by the same reference numerals and redundant description may be omitted. When only a part of a configuration is described in each embodiment, configurations of other embodiments described previously can be applied to other parts of the configuration. Further, not only combinations of configurations explicitly shown in the description of each embodiment, but also configurations of a plurality of embodiments can be partially combined with each other even if not explicitly shown, provided that there is no particular problem in the combination.

### First Embodiment

A semiconductor device of the present embodiment is applied to, for example, a mobile object using a rotary electric machine as a drive source. The mobile object is, for example, an electric vehicle such as a battery electric vehicle (BEV), a hybrid electric vehicle (HEV), or a plug-in hybrid electric vehicle (PHEV), an electric flying object such as a drone or an electric vertical take-off and landing aircraft (eVTOL), a ship, a construction machine, or an agricultural machine. Hereinafter, an example applied to a vehicle will be described.

### Vehicle Drive System

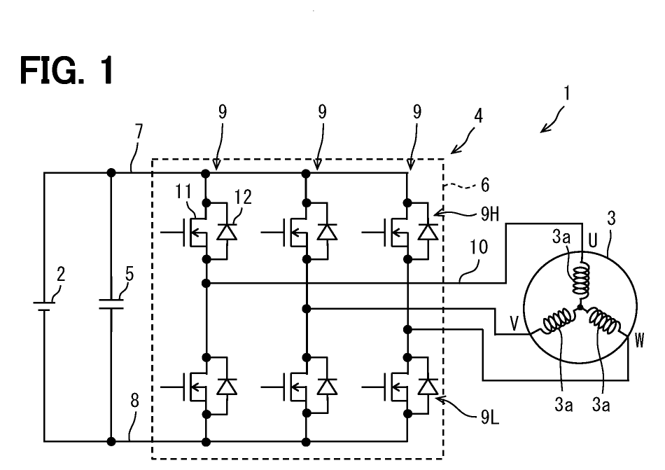

As shown in FIG. 1, a vehicle drive system 1 includes a direct current (DC) power supply 2, a motor generator 3, and a power conversion circuit 4.

The DC power supply 2 is a DC voltage source composed of a chargeable/dischargeable secondary battery. The secondary battery is, for example, a lithium ion battery, a nickel metal hydride battery, or the like. The motor generator 3 is a three-phase alternating current (AC) rotary electric machine. The motor generator3 functions as a traveling drive source of the vehicle, that is, an electric motor. The motor generator 3 functions as a generator during regeneration. The power conversion circuit 4 performs power conversion between the DC power supply 2 and the motor generator 3.

### Power Conversion Circuit

FIG. 1 shows an example of the power conversion circuit 4. The power conversion circuit 4 illustrated in FIG. 1 includes a smoothing capacitor 5 and an inverter 6.

The smoothing capacitor 5 mainly smoothes a DC voltage supplied from the DC power supply 2. The smoothing capacitor 5 is connected to a P line 7 which is a power supply line on a high potential side and an N line 8 which is a power supply line on a low potential side. The P line 7 is connected to a positive electrode of the DC power supply 2, and the N line 8 is connected to a negative electrode of the DC power supply 2. A positive electrode of the smoothing capacitor 5 is connected to the P line 7 between the DC power supply 2 and the inverter 6. A negative electrode of the smoothing capacitor 5 is connected to the N line 8 between the DC power supply 2 and the inverter 6. The smoothing capacitor 5 is connected in parallel to the DC power supply 2.

The inverter 6 is a DC-AC conversion circuit. The inverter 6 converts a DC voltage into a three-phase AC voltage according to switching control by a control circuit and outputs the voltage to the motor generator 3. Thus, the motor generator 3 is driven to generate a predetermined torque. The inverter 6 converts a three-phase AC voltage generated by the motor generator 3 receiving rotational force from wheels during regenerative braking of the vehicle into a DC voltage according to switching control by the control circuit, and outputs the voltage to the P line 7. Thus, the inverter 6 performs bidirectional power conversion between the DC power supply 2 and the motor generator 3.

The inverter 6 is configured to include upper and lower arm circuits 9 for three phases. The upper and lower arm circuit 9 may be referred to as a leg. The upper and lower arm circuit 9 has an upper arm 9H and a lower arm 9L. The upper arm 9H and the lower arm 9L are connected in series between the P line 7 and the N line 8 with the upper arm 9H on the P line 7 side. Hereinafter, the upper arm 9H and the lower arm 9L may be simply referred to as arms 9H and 9L.

A connection point between the upper arm 9H and the lower arm 9L, that is, a midpoint of the upper and lower arm circuit 9 is connected to a winding 3a of a corresponding phase in the motor generator 3 via an output line 10. The inverter 6 has six arms 9H and 9L. Each of the arms 9H and 9L is configured to include a switching element. The number of switching elements constituting each of the arms 9H and 9L is not particularly limited. It may be one, or plural (for example, two). In the case where one arm includes multiple switching elements, the multiple switching elements are connected in parallel to each other, and are driven on and off at the same timing by a common gate drive signal (drive voltage).

The illustrated switching element is an n-channel MOSFET 11. MOSFET is an abbreviation for Metal Oxide Semiconductor Field Effect Transistor. In the upper arm 9H, a drain of the MOSFET 11 is connected to the P line 7. In the lower arm 9L, a source of the MOSFET 11 is connected to the N line 8. A source of the MOSFET 11 in the upper arm 9H and a drain of the MOSFET 11 in the lower arm 9L are connected to each other.

A freewheeling diode 12 is connected in anti-parallel to each of the MOSFETs 11. The diode 12 may be a parasitic diode (body diode) of the MOSFET 11 or an external diode. An anode of the diode 12 is connected to the source of the corresponding MOSFET 11, and a cathode is connected to the drain of the corresponding MOSFET 11.

The switching element is not limited to the MOSFET 11. For example, an IGBT may be adopted. IGBT is an abbreviation for Insulated Gate Bipolar Transistor. Also in the case of the IGBT, a freewheeling diode is connected in anti-parallel.

The power conversion circuit 4 may include a converter. The converter is a DC-DC conversion circuit configured to be capable of converting a DC voltage into a DC voltage of a different value, for example. The converter is provided between the DC power supply 2 and the smoothing capacitor 5. The converter is configured to include, for example, a reactor and the upper and lower arm circuit 9 described above. According to this configuration, it is possible to step up and down the voltage. The power conversion circuit 4 may include a filter capacitor. The filter capacitor is provided between the DC power supply 2 and the converter.

The power conversion circuit 4 may include a snubber circuit. The snubber circuit is connected in parallel to the upper and lower arm circuit 9. The snubber circuit reduces inductance of the upper and lower arm circuit 9. The snubber circuit absorbs a transient high voltage generated during switching of the switching elements (MOSFETs 11) constituting the upper and lower arm circuit 9, a so-called switching surge. Thus, the inverter 6 is capable of high-speed switching.

The power conversion circuit 4 may include a drive circuit for the switching elements constituting the inverter 6 and the like. The drive circuit supplies a drive voltage to a gate of the MOSFET 11 of a corresponding arm based on a drive command from the control circuit. The drive circuit drives, that is, turns on and off the corresponding MOSFET 11 by applying the drive voltage. The drive circuit may be referred to as a driver.

The power conversion circuit 4 may include a control circuit for the switching element. The control circuit generates a drive command for operating the MOSFET 11 and outputs the drive command to the drive circuit. The control circuit generates the drive command based on, for example, a torque request input from a host ECU (not shown) and signals detected by various sensors. ECU is an abbreviation for Electronic Control Unit.

Examples of the various sensors include a current sensor, a rotation angle sensor, and a voltage sensor. The current sensor detects a phase current flowing through the winding 3a of each phase. The rotation angle sensor detects a rotation angle of a rotor of the motor generator 3. The voltage sensor detects a voltage across the smoothing capacitor 5. The control circuit outputs, for example, a PWM signal as the drive command. The control circuit is configured to include, for example, a processor and a memory. PWM is an abbreviation for Pulse Width Modulation.

### Semiconductor Device

Hereinafter, a thickness direction of the semiconductor element (semiconductor substrate) is defined as a Z direction. One direction orthogonal to the Z direction is defined as a Y direction. The Y direction corresponds to a lateral direction. A direction orthogonal to both the Z direction and the Y direction is defined as an X direction. The X direction, the Y direction, and the Z direction are in a positional relationship orthogonal to each other. Unless otherwise specified, a shape viewed in plan from the Z direction, in other words, a shape along an XY plane defined by the X direction and the Y direction is referred to as a planar shape. A plan view from the Z direction may be simply referred to as a plan view.

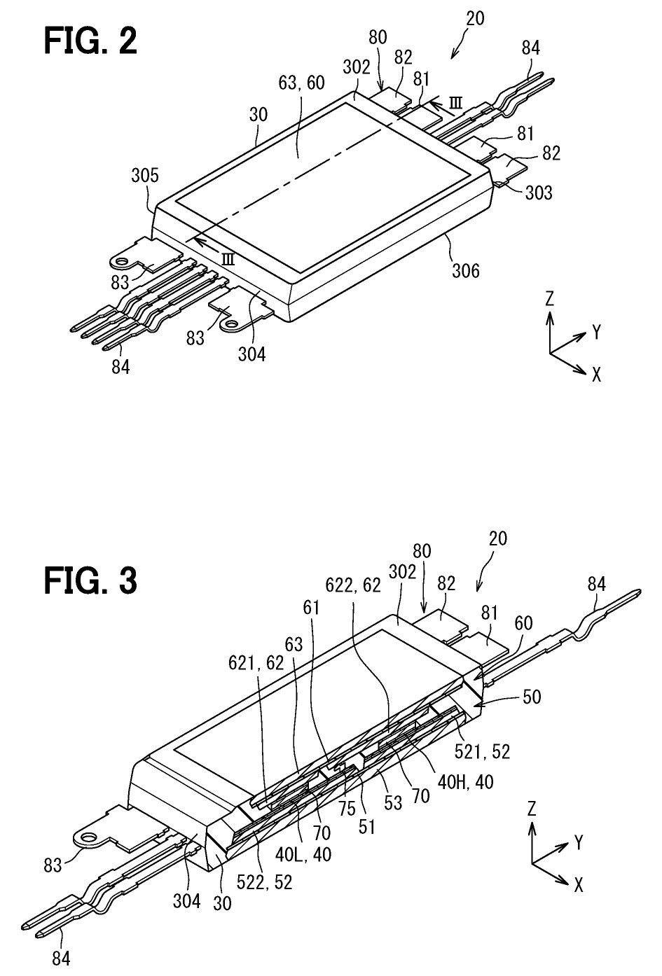

A semiconductor device 20 constitutes the above-described upper and lower arm circuit 9, that is, the inverter 6. The exemplary semiconductor device 20 constitutes one of the upper and lower arm circuits 9, that is, the upper and lower arm circuit 9 for one phase. The semiconductor device 20 may be referred to as a semiconductor module, a power module, or the like. As shown in FIG. 2 and FIG. 3, the semiconductor device 20 includes a sealing body 30, semiconductor elements 40, substrates 50 and 60, spacers 70, a joint portion 75, and external connection terminals 80.

The sealing body 30 seals a part of other elements constituting the semiconductor device 20. The remaining part of the other elements is exposed to the outside of the sealing body 30. The sealing body 30 is formed using a resin material. The exemplary sealing body 30 is molded by a transfer molding method using epoxy resin as a material. Such a sealing body 30 may be referred to as a mold resin, a sealing resin body, or the like.

The sealing body 30 has a substantially rectangular planar shape. The sealing body 30 has one surface 301, a back surface 302, and side surfaces 303, 304, 305, and 306 as surfaces forming an outer shell. The back surface 302 is a surface opposite to the one surface 301 in the Z direction. The one surface 301 and the back surface 302 are, for example, flat surfaces. The side surface 304 is a surface opposite to the side surface 303 in the Y direction. The side surface 306 is a surface opposite to the side surface 305 in the X direction.

The semiconductor element 40 is formed by forming a switching element on a semiconductor substrate made of a material such as a wide bandgap semiconductor having a wider bandgap than silicon. Examples of the wide bandgap semiconductor include silicon carbide, gallium nitride, gallium oxide, and diamond. The semiconductor element 40 may be referred to as a power element, a semiconductor chip, or the like.

The exemplary semiconductor element 40 is formed by forming the above-described n-channel MOSFET 11 on a semiconductor substrate made of SiC. The MOSFET 11 has a vertical structure in which a main current flows in the thickness direction of the semiconductor element 40 (semiconductor substrate), that is, in the Z direction. The semiconductor element 40 has main electrodes of the switching element on both surfaces thereof in the thickness direction, that is, in the Z direction. The semiconductor element 40 has a drain electrode 41 on one surface and a source electrode 42 on a back surface as the main electrodes. When the diode 12 is a parasitic diode, the source electrode 42 also serves as an anode electrode, and the drain electrode 41 also serves as a cathode electrode. The diode 12 may be configured on a chip separate from the MOSFET 11. The drain electrode 41 is a main electrode on a high potential side, and the source electrode 42 is a main electrode on a low potential side.

The semiconductor element 40 has a substantially rectangular planar shape. The semiconductor element 40 has a pad 43 formed at a position different from the source electrode 42 on the back surface. The source electrode 42 and the pad 43 are exposed from a protective film (not shown) formed on the back surface of the semiconductor substrate. The drain electrode 41 is formed on substantially the entire one surface. The source electrode 42 is formed on a part of the back surface of the semiconductor element 40. The pad 43 is an electrode for signals. The pads 43 include a pad for a gate electrode. The exemplary pad 43 is formed at an end opposite to a formation region of the source electrode 42 in the Y direction.

The semiconductor device 20 includes a plurality of semiconductor elements 40. The plurality of semiconductor elements 40 may include a plurality of types of semiconductor elements having different specifications. Configurations of all the semiconductor elements 40 may be common to each other as the exemplary semiconductor device 20. The plurality of semiconductor elements 40 include a semiconductor element 40H constituting the upper arm 9H and a semiconductor element 40L constituting the lower arm 9L. The semiconductor element 40H may be referred to as an upper arm element, or a first semiconductor element. The semiconductor element 40L may be referred to as a lower arm element, or a second semiconductor element.

The semiconductor elements 40H and 40L are arranged in the Y direction. The semiconductor elements 40H and 40L are disposed at substantially the same position as each other in the Z direction. The drain electrodes 41 of the semiconductor elements 40H and 40L face the substrate 50. The source electrodes 42 of the semiconductor elements 40H and 40L face the substrate 60. When the number of switching elements constituting each of the arms 9H and 9L is, for example, two, the semiconductor device 20 includes two semiconductor elements 40H and two semiconductor elements 40L. The two semiconductor elements 40H are arranged in the X direction. Similarly, the two semiconductor elements 40L are arranged in the X direction.

The semiconductor element 40H is disposed such that the pad 43 is located on the side surface 303 side with respect to the source electrode 42. The semiconductor element 40L is disposed such that the pad 43 is located on the side surface 304 side with respect to the source electrode 42.

The substrates 50 and 60 are disposed so as to sandwich the plurality of semiconductor elements 40 in the Z direction. The substrates 50 and 60 are disposed such that at least parts thereof face each other in the Z direction. The substrates 50 and 60 enclose all of the plurality of semiconductor elements 40 in a plan view. The substrate 50 is disposed on the drain electrode 41 side. The substrate 60 is disposed on the source electrode 42 side. The substrate 50 is electrically connected to the drain electrode 41 and provides a wiring function. The substrate 60 is electrically connected to the source electrode 42 and provides a wiring function. The substrates 50 and 60 provide a heat dissipation function of dissipating heat generated by the semiconductor element 40.

The substrate 50 includes an insulating base material 51, a front surface metal body 52, and a back surface metal body 53. The substrate 50 may be referred to as a first substrate. The substrate 60 includes an insulating base material 61, a front surface metal body 62, and a back surface metal body 63. The substrate 60 may be referred to as a second substrate.

The insulating base materials 51 and 61 are resin base materials containing resin as a material. The exemplary insulating base materials 51 and 61 contain epoxy resin as a material. The insulating base material 51 electrically separates the front surface metal body 52 and the back surface metal body 53. The insulating base material 61 electrically separates the front surface metal body 62 and the back surface metal body 63.

The front surface metal bodies 52 and 62 and the back surface metal bodies 53 and 63 are provided as metal plates or metal foils. The front surface metal bodies 52 and 62 and the back surface metal bodies 53 and 63 are made of a metal having good electrical conductivity and thermal conductivity, such as copper or aluminum. The front surface metal bodies 52 and 62 are patterned. The front surface metal bodies 52 and 62 may have a plating film such as a nickel-based or gold-based film on metal surfaces. The front surface metal body 52 has a P wiring 521 and a relay wiring 522. The P wiring 521 and the relay wiring 522 are electrically separated by a predetermined gap (interval), and the sealing body 30 is filled in this gap.

The P wiring 521 is connected to a P terminal 81 and the drain electrode 41 of the semiconductor element 40H. The P wiring 521 electrically connects the P terminal 81 and the drain electrode 41 of the semiconductor element 40H. The relay wiring 522 is connected to the drain electrode 41 of the semiconductor element 40L, the joint portion 75, and an O terminal 83. The relay wiring 522 electrically connects the O terminal 83 and the drain electrode 41 of the semiconductor element 40L. The exemplary P wiring 521 has a substantially rectangular planar shape. The relay wiring 522 has a substantially rectangular planar shape. The P wiring 521 and the relay wiring 522 are arranged in the Y direction.

The P terminal 81 is connected near an end on the side surface 303 side in the P wiring 521. The O terminal 83 is connected near an end on the side surface 304 side in the relay wiring 522. The drain electrode 41 of the semiconductor element 40H is connected to the P wiring 521 at a position closer to the relay wiring 522 than a joined portion with the P terminal 81. The drain electrode 41 of the semiconductor element 40L is connected to the relay wiring 522 at a position closer to the P wiring 521 than a joined portion with the O terminal 83. The joint portion 75 is connected to the relay wiring 522 at a position closer to the P wiring 521 than the semiconductor element 40L.

The front surface metal body 62 has an N wiring 621 and a relay wiring 622. The N wiring 621 and the relay wiring 622 are electrically separated by a predetermined gap (interval). The sealing body 30 is filled in this gap. The N wiring 621 is connected to an N terminal 82 and the source electrode 42 of the semiconductor element 40L. The N wiring 621 electrically connects the N terminal 82 and the source electrode 42 of the semiconductor element 40L. The relay wiring 622 is connected to the source electrode 42 of the semiconductor element 40H and the joint portion 75. The relay wiring 622 electrically connects the source electrode 42 of the semiconductor element 40H and the drain electrode 41 of the semiconductor element 40L via the joint portion 75.

The exemplary N wiring 621 has a substantially U-shape in a plan view. The N wiring 621 has a base portion extending in the X direction, and a pair of extending portions continuous with the base portion and extending in the Y direction from both ends of the base portion. The relay wiring 622 is disposed between the pair of extending portions of the N wiring 621. The relay wiring 622 has the same or similar shape as a baseball home plate in a plan view. The base portion of the N wiring 621 and the relay wiring 622 are arranged in the Y direction. The extending portions of the N wiring 621 and the relay wiring 622 are arranged in the X direction.

The source electrode 42 of the semiconductor element 40L is connected to the base portion of the N wiring 621. The N terminal 82 is connected to the extending portion of the N wiring 621. The semiconductor element 40L is connected near an end on the side surface 304 side in the N wiring 621. The N terminal 82 is connected near an end on the side surface 303 side in the N wiring 621. The source electrode 42 of the semiconductor element 40H is connected to the relay wiring 622. The joint portion 75 is connected to the relay wiring 622 at a position closer to the base portion of the N wiring 621 than the semiconductor element 40H.

The back surface metal bodies 53 and 63 are electrically separated from the front surface metal bodies 52 and 62 by the insulating base materials 51 and 61, respectively. The exemplary back surface metal bodies 53 and 63 are so-called solid conductors disposed on substantially entire back surfaces of the insulating base materials 51 and 61, respectively. The back surface metal body 53 is exposed from the one surface 301 of the sealing body 30, and the back surface metal body 63 is exposed from the back surface 302. The back surface metal body 53 is exposed substantially flush with the one surface 301. The back surface metal body 63 is exposed substantially flush with the back surface 302.

The spacer 70 provides a spacer function of ensuring a predetermined distance between the semiconductor element 40 and the substrate 60. The spacer 70 ensures, for example, a height for electrically connecting a corresponding signal terminal 84 to the pad 43 of the semiconductor element 40. The spacer 70 is located in an intermediate position of an electric conduction and heat conduction path between the source electrode 42 of the semiconductor element 40 and the substrate 60, and provides a wiring function and a heat dissipation function. The spacer 70 contains a metal material having good electrical conductivity and thermal conductivity, such as copper. The spacer 70 may have a plating film on a surface thereof. The spacer 70 is a columnar body having a substantially rectangular planar shape having substantially the same size as the source electrode 42 in a plan view.

The spacer 70 may be referred to as a terminal, a metal block body, or the like. The semiconductor device 20 includes the same number of spacers 70 as the semiconductor elements 40. Specifically, two spacers 70 are provided. One of the spacers 70 electrically connects the source electrode 42 of the semiconductor element 40H and the relay wiring 622. The other one of the spacers 70 electrically connects the source electrode 42 of the semiconductor element 40L and the N wiring 621.

The joint portion 75 electrically connects the relay wirings 522 and 622. That is, the joint portion 75 electrically connects the upper arm 9H and the lower arm 9L. The joint portion 75 is provided between the semiconductor element 40H and the semiconductor element 40L. The joint portion 75 is disposed in an overlapping region of the relay wirings 522 and 622 in a plan view. The exemplary joint portion 75 is a metal body provided separately from the front surface metal bodies 52 and 62. One of ends of the joint portion 75 is connected to the relay wiring 522, and the other one of the ends is connected to the relay wiring 622. The joint portion 75 contains a metal material having good electrical conductivity and thermal conductivity, such as copper. The joint portion 75 may be continuously and integrally connected to the front surface metal bodies 52 and 62. That is, the joint portion 75 may be provided integrally with the front surface metal bodies 52 and 62 as a part of the substrates 50 and 60. A part of the joint portion 75 may be provided as a part of the substrate 50, and another part of the joint portion 75 may be provided as a part of the substrate 60.

The joint portion 75 of the present embodiment has a first extension portion 75a and a second extension portion 75b extending in the Z direction, and an intermediate portion 75c interconnecting the first extension portion 75a and the second extension portion 75b in the Y direction. The joint portion 75 extends in a crank shape from the relay wiring 622 toward the relay wiring 522. The joint portion 75 has a structure that is easily deformed in the Z direction. Note that the deformation direction of the joint portion 75 is not limited to the Z direction. It suffices that the joint portion 75 has a structure capable of allowing deformation at least in the Z direction.

One of ends of the first extension portion 75a is connected to a surface 622a of the relay wiring 622 via a bonding material 90. One of ends of the second extension portion 75b is connected to a surface 522a of the relay wiring 522 via the bonding material 90. The first extension portion 75a and the second extension portion 75b are disposed shifted in the Y direction. Another end of the first extension portion 75a and another end of the second extension portion 75b are connected via the intermediate portion 75c.

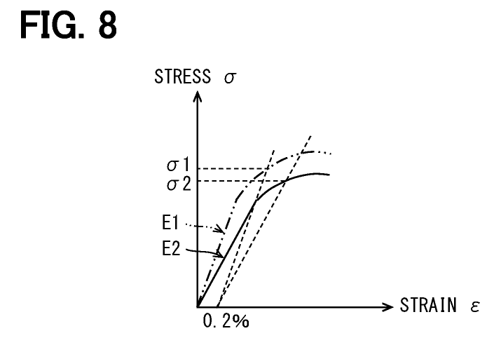

FIG. 8 is a diagram showing a relationship between stress and strain in the joint portion 75 and the spacer 70. In FIG. 8, description will be made assuming that materials of the joint portion 75 and the spacer 70 are both mainly made of copper. In FIG. 8, the joint portion 75 is indicated by a solid line, and the spacer 70 is indicated by a two-dot chain line. In the stress-strain diagram of FIG. 8, a slope of a graph in an elastic region corresponds to a Young's modulus. A Young's modulus E2 of the joint portion 75 is smaller than a Young's modulus E1 of the spacer 70. The larger the Young's modulus, the larger stress is required to distort a member. The larger the Young's modulus, the higher the stiffness of a material. In the present embodiment, in the elastic region, the stiffness of the joint portion 75 is lower than the stiffness of the spacer 70. In the elastic region, the joint portion 75 is more easily deformed than the spacer 70.

Further, since a distinct yield point does not appear in copper, a stress at a time when a strain of 0.2% occurs is evaluated as a proof stress. This stress is referred to as a 0.2% proof stress and is regarded as a yield point. The yield point refers to a point of transition from elastic deformation to plastic deformation. In the present embodiment, a yield point σ2 of the joint portion 75 is smaller than a yield point σ1 of the spacer 70. In the joint portion 75 having a small yield point σ2, the transition from the elastic deformation to the plastic deformation occurs with a small force.

In the joint portion 75, permanent deformation starts with a small force. Generally, an amount of deformation of permanent deformation tends to be larger than an amount of deformation of elastic deformation. Even in a plastic region, the joint portion 75 is more easily deformed than the spacer 70. Thus, in the elastic region and the plastic region, the joint portion 75 is more easily deformed than the spacer 70. It can be said that the joint portion 75 has a structure more easily deformed than the spacer 70.

The external connection terminal 80 is a terminal for electrically connecting the semiconductor device 20 to an external device. The external connection terminal 80 is formed using a metal material having good electrical conductivity such as copper. The external connection terminal 80 is, for example, a plate material. The external connection terminal 80 may be referred to as a lead or the like. The external connection terminal 80 includes the P terminal 81, the N terminal 82, the O terminal 83, and the signal terminal 84. Since the P terminal 81, the N terminal 82, and the O terminal 83 are electrically connected to the main electrodes of the semiconductor elements 40, they may be referred to as main terminals. The P terminal 81 and the N terminal 82 may be referred to as power supply terminals.

The P terminal 81 is connected near one end in the Y direction in the P wiring 521. A part of the P terminal 81 is covered with the sealing body 30, and another part protrudes to the outside of the sealing body 30. A joined portion with the P wiring 521 in the P terminal 81 is covered with the sealing body 30. The exemplary P terminal 81 extends substantially in the Y direction. The P terminal 81 protrudes from the side surface 303. The semiconductor device 20 includes two P terminals 81.

The N terminal 82 is connected to the extending portion of the N wiring 621. A part of the N terminal 82 is covered with the sealing body 30, and another part protrudes to the outside of the sealing body 30. A joined portion with the N wiring 621 in the N terminal 82 is covered with the sealing body 30. The exemplary N terminal 82 extends substantially in the Y direction, which is the same direction as the P terminal 81. The N terminal 82 protrudes from the side surface 303. The semiconductor device 20 includes two N terminals 82 individually connected to the extending portions of the N wiring 621.

The O terminal 83 is connected near one end in the Y direction in the relay wiring 522. A part of the O terminal 83 is covered with the sealing body 30, and another part protrudes to the outside of the sealing body 30. A joined portion with the relay wiring 522 in the O terminal 83 is covered with the sealing body 30. The exemplary O terminal 83 extends substantially in the Y direction opposite to the P terminal 81 and the N terminal 82. The O terminal 83 protrudes from the side surface 304.

The signal terminal 84 is electrically connected to the pad 43 of the corresponding semiconductor element 40. The signal terminals 84 include a signal terminal connected to the pad 43 of the semiconductor element 40H and a signal terminal connected to the pad 43 of the semiconductor element 40L. The exemplary signal terminal 84 is connected to the corresponding pad 43 via a bonding wire (not shown). The signal terminal 84 extends substantially in the Y direction in a plan view. Of the signal terminal 84, a part including a connection portion with the pad 43 is covered with the sealing body 30, and another part protrudes from the sealing body 30.

The signal terminal 84 connected to the pad 43 of the semiconductor element 40H protrudes to the outside of the sealing body 30 from the side surface 303. The P terminals 81, the N terminals 82, and the signal terminals 84 on the upper arm 9H side are arranged in the X direction. In the X direction, these terminals are arranged in the order of the N terminal 82, the P terminal 81, the signal terminals 84, the P terminal 81, and the N terminal 82. The signal terminal 84 connected to the pad 43 of the semiconductor element 40L protrudes to the outside of the sealing body 30 from the side surface 304. The O terminals 83 and the signal terminals 84 on the lower arm 9L side are arranged in the X direction. In the X direction, these terminals are arranged in the order of the O terminal 83, the signal terminals 84, and the O terminal 83.

The semiconductor device 20 includes the bonding material 90. The bonding material 90 may be solder or a sintered material. The drain electrode 41 of the semiconductor element 40 is connected to the front surface metal body 52 via the bonding material 90. The source electrode 42 of the semiconductor element 40 is connected to the spacer 70 via the bonding material 90. The spacer 70 is connected to the front surface metal body 62 via the bonding material 90. The joint portion 75 is connected to the front surface metal bodies 52 and 62 via the bonding material 90. Note that the plurality of bonding materials 90 may be made of a common material to each other, or a material of some bonding materials 90 may be different from a material of other bonding materials 90.

The P terminals 81, the N terminals 82, and the O terminals 83 may be connected to the corresponding front surface metal bodies 52 and 62 by the above-described bonding materials 90. The P terminals 81, the N terminals 82, and the O terminals 83 may be solid-phase joined to the corresponding front surface metal bodies 52 and 62. Examples of the solid-phase joining include ultrasonic joining, room temperature joining, friction stir joining, diffusion joining, and friction welding.

As described above, in the semiconductor device 20, the sealing body 30 seals the plurality of semiconductor elements 40 constituting the upper and lower arm circuit 9 for one phase. The sealing body 30 integrally seals the semiconductor elements 40, the substrate 50, the substrate 60, the spacer 70, the joint portion 75, and the external connection terminals 80. The sealing body 30 seals the insulating base materials 51 and 61 and the front surface metal bodies 52 and 62 of the substrates 50 and 60.

The semiconductor element 40 is disposed between the substrates 50 and 60 in the Z direction. The semiconductor element 40 is sandwiched by the substrates 50 and 60 disposed facing each other. Thus, heat of the semiconductor element 40 can be dissipated to both sides in the Z direction. The semiconductor device 20 has a double-sided heat dissipation structure. The back surface metal body 53 is exposed from the sealing body 30 substantially flush with the one surface 301. The back surface metal body 63 is exposed from the sealing body 30 substantially flush with the back surface 302. Due to an exposed structure of the back surface metal bodies 53 and 63, heat dissipation performance can be enhanced.

### Method for Manufacturing Semiconductor Device

First, elements constituting the semiconductor device 20 are prepared. Next, a first connection step is performed. In this step, the semiconductor element 40 is placed on the front surface metal body 52 of the substrate 50 such that the drain electrode 41 faces the front surface metal body 52. Then, the drain electrode 41 and the front surface metal body 52 are electrically connected. In the present embodiment, the drain electrode 41 and the front surface metal body 52 are joined by the bonding material 90. In the first connection step, the joint portion 75 and the front surface metal body 52 are joined by the bonding material 90. By the bonding material 90, the P terminal 81 and the O terminal 83 are joined to the front surface metal body 52.

Next, a wire bonding step is performed. In this step, the pad 43 of the semiconductor element 40 and the signal terminal 84 are connected via a bonding wire. Specifically, the signal terminal 84 and the corresponding pad 43 of the semiconductor element 40L are connected via a bonding wire. The signal terminal 84 and the corresponding pad 43 of the semiconductor element 40H are connected via a bonding wire.

Next, a second connection step is performed. In this step, the source electrode 42 of the semiconductor element 40 and the substrate 60 which is a second wiring member are electrically connected. In the present embodiment, the source electrode 42 and the front surface metal body 62 are joined via the bonding material 90 and the spacer 70. At this time, the substrate 50 to which the semiconductor element 40 is connected and the substrate 60 are relatively displaced in a direction in which facing surfaces of the front surface metal bodies 52 and 62 approach each other. The N terminal 82 and the front surface metal body 62 are joined by the bonding material 90.

Next, a molding step of the sealing body 30 is performed. For example, the sealing body 30 is molded by the transfer molding method described above. For example, the sealing body 30 is molded in a state where the back surfaces of the substrates 50 and 60 are pressed against and brought into close contact with cavity wall surfaces of a molding die. The inside of the semiconductor device 20 is filled with the sealing body 30. The sealing body 30 forms an outer shell of the semiconductor device 20. Note that the back surfaces of the substrates 50 and 60 are exposed from the sealing body 30. Next, by removing unnecessary parts such as tie bars in a lead frame, the semiconductor device 20 can be obtained.

### Triple Junction, Roughened Portion, and Non-Roughened Portion

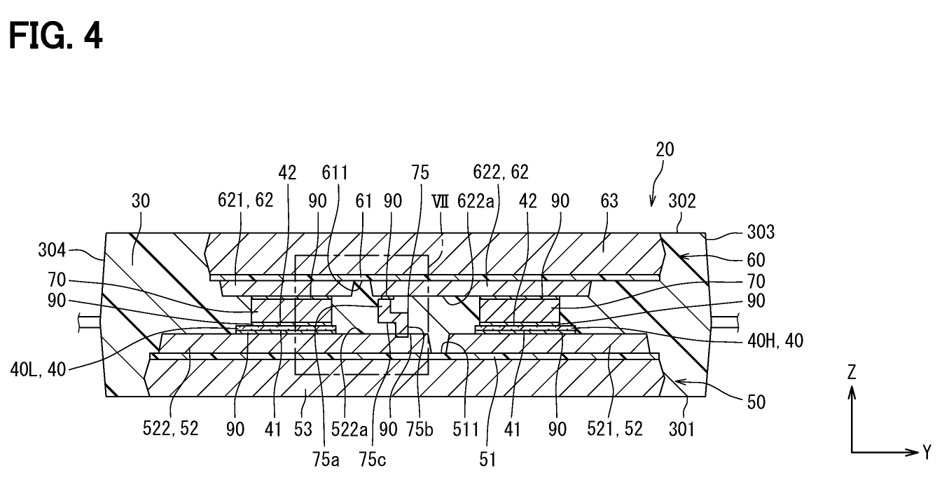

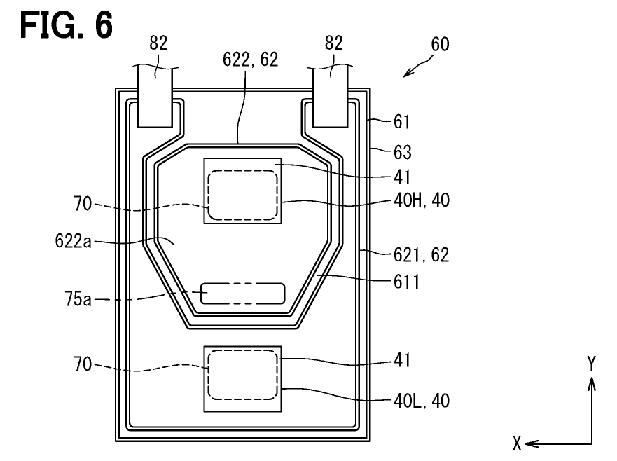

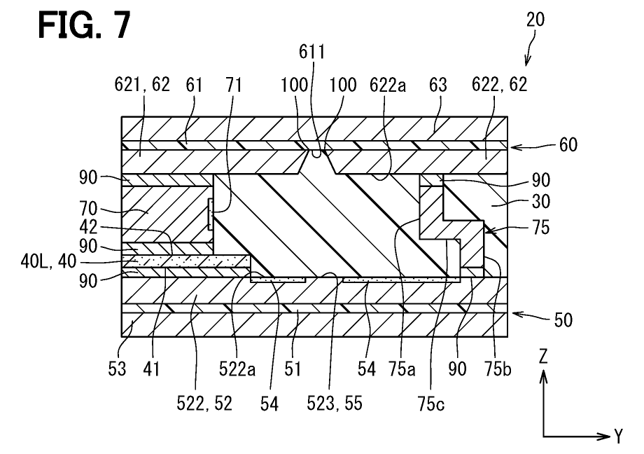

As shown in FIG. 4, FIG. 6, and FIG. 7, the insulating base material 61 has an exposed surface 611 exposed from the front surface metal body 62. The exposed surface 611 is a portion exposed by a gap between adjacent wirings. The exposed surface 611 is exposed by a gap between the N wiring 621 and the relay wiring 622. Further, the exposed surface 611 is located between the spacer 70 and the joint portion 75. The exposed surface 611 is exposed from the front surface metal body 62 and is in close contact with the sealing body 30. Since the exposed surface 611 is in close contact with the sealing body 30, the N wiring 621 and the relay wiring 622 are insulated from each other in the Y direction. Since a distance between the N wiring 621 and the relay wiring 622 can be reduced while maintaining a dielectric strength, this leads to miniaturization.

Further, as illustrated in FIG. 7, the semiconductor device 20 includes a triple junction 100 where the sealing body 30, the insulating base material 61, and the front surface metal body 62 overlap. The triple junction 100 is configured by the insulating base material 61 having the exposed surface 611. The triple junction 100 includes the triple junction 100 of the sealing body 30, the insulating base material 61, and the N wiring 621, and the triple junction 100 of the sealing body 30, the insulating base material 61, and the relay wiring 622, at the exposed surface 611.

The sealing body 30 is cooled and cured inside the molding die. Cooling and curing of the sealing body 30 proceed from a surface portion toward a central portion of the molding die. Therefore, a temperature variation occurs between a surface portion and a central portion of the sealing body 30. A temperature of the central portion is higher than that of the surface portion. The sealing body 30 shrinks due to such temperature variation. Tensile stress is generated in the sealing body 30 from the surface portion toward the central portion. In the configuration including the triple junction 100, stress tends to concentrate on the triple junction 100 during shrinkage of the sealing body 30. Therefore, in the present embodiment, a member that is more easily deformed than the spacer 70 is adopted for the joint portion 75 to suppress concentration of stress on the triple junction 100.

The front surface metal body 52 further includes, on the surface 522a of the relay wiring 522, a low adhesion portion 55 and a high adhesion portion 54 having higher adhesion to the sealing body 30 than the low adhesion portion 55. The exemplary semiconductor device 20 includes a roughened portion as the high adhesion portion 54 and a non-roughened portion as the low adhesion portion 55. It can be said that the substrate 50 has a roughened portion and a non-roughened portion. The high adhesion portion 54 is a roughened portion of the surface 522a. The low adhesion portion 55 is a non-roughened portion of the surface 522a, that is, a portion excluding the high adhesion portion 54.

The high adhesion portion 54 can be formed by laser irradiation, blasting, blackening treatment, roughening plating, or the like. The exemplary high adhesion portion 54 is a roughened portion by laser irradiation. The high adhesion portion 54 is obtained by irradiating a plating film formed on the surface of the front surface metal body 52 with a pulse laser. The high adhesion portion 54 is made of an uneven oxide film derived from a main metal constituting the plating film and having fine unevenness on its surface. As shown in FIG. 7, a similar high adhesion portion 71 is provided on a side surface of the spacer 70. In describing the arrangement of the high adhesion portion 54 and the low adhesion portion 55, in order to simplify the description, a portion facing the exposed surface 611 in the surface 522a is referred to as a facing surface 523.

As shown in FIG. 7, the high adhesion portion 54 is provided on the surface 522a excluding the facing surface 523 between the semiconductor element 40L and the joint portion 75. The high adhesion portion 54 is provided on the surface 522a so as to sandwich the facing surface 523 from both sides. The low adhesion portion 55 is provided on the facing surface 523. The low adhesion portion 55 is provided so as to overlap with at least a part of the exposed surface 611 in the Z direction. The high adhesion portion 54 and the low adhesion portion 55 are alternately arranged in the Y direction.

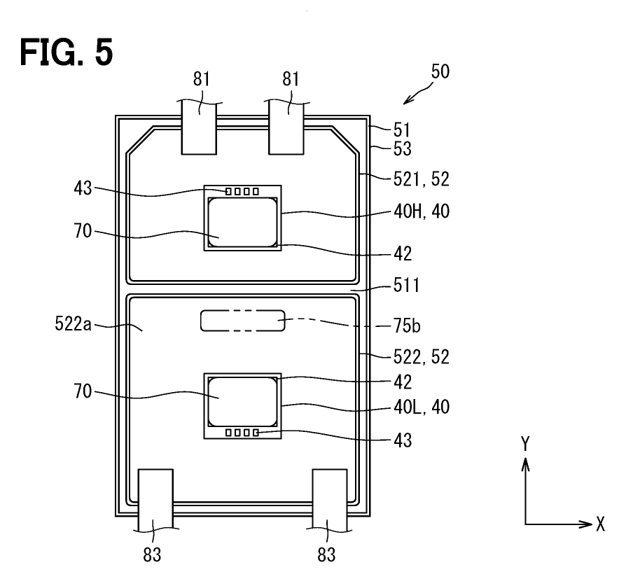

Note that as shown in FIG. 4 and FIG. 5, the insulating base material 51 also has an exposed surface 511 exposed from the front surface metal body 52. The exposed surface 511 is exposed by a gap between the P wiring 521 and the relay wiring 522. The exposed surface 511 is exposed from the front surface metal body 52 and is in close contact with the sealing body 30. In addition to the two triple junctions 100 described so far, the semiconductor device 20 includes a triple junction of the sealing body 30, the insulating base material 51, and the P wiring 521, and a triple junction of the sealing body 30, the insulating base material 51, and the relay wiring 522. The front surface metal body 62 may include the low adhesion portion 55 and the high adhesion portion 54 on the surface 622a. The high adhesion portion 54 and the low adhesion portion 55 may be applied to one of the surface 522a and the surface 622a, or may be applied to both.

### Summary of First Embodiment

The semiconductor device 20 of the present embodiment includes the substrates 50 and 60, the semiconductor element 40, the spacer 70, the joint portion 75, and the sealing body 30. The insulating base material 61 of the substrate 60 has the exposed surface 611. The exposed surface 611 is exposed from the front surface metal body 62 between the spacer 70 and the joint portion 75, and is in close contact with the sealing body 30. The joint portion 75 has a structure that is more easily deformable than the spacer 70.

As described above, the sealing body 30 shrinks with curing. Tensile stress is generated in the sealing body 30 from the surface portion toward the central portion. In the present embodiment, since the joint portion 75 is more easily deformable than the spacer 70, the joint portion 75 is easily deformed so as to follow the shrinkage of the sealing body 30. During shrinkage of the sealing body 30, the joint portion 75 is suppressed from strutting between the substrates 50 and 60. Therefore, concentration of stress on the triple junction 100 is suppressed. Occurrence of cracks or the like in the insulating base material 61 at the triple junction 100 is suppressed. Loss of insulation properties of the insulating base material 61 is suppressed.

Further, the joint portion 75 of the present embodiment has a structure easily deformed in the Z direction. As an example, the joint portion 75 has a crank shape. According to this, during shrinkage of the sealing body 30, the joint portion 75 is effectively suppressed from strutting between the substrates 50 and 60.

In the present embodiment, the Young's modulus E2 of the joint portion 75 is smaller than the Young's modulus E1 of the spacer 70. According to this, in the elastic region, the joint portion 75 is more easily deformed than the spacer 70. In the elastic region, concentration of stress on the triple junction 100 is suppressed. The yield point σ2 of the joint portion 75 of the present embodiment is smaller than the yield point σ1 of the spacer 70. Also in the plastic region, concentration of stress on the triple junction 100 is suppressed.

The semiconductor device 20 of the present embodiment further includes the low adhesion portion 55 and the high adhesion portion 54 having higher adhesion to the sealing body 30 than the low adhesion portion 55. The low adhesion portion 55 is provided on the facing surface 523 so as to overlap with the exposed surface 611 in the Z direction. The high adhesion portion 54 is provided on the surface 522a so as to sandwich the facing surface 523 from both sides in the Y direction.

Unlike the present embodiment, in a form in which the high adhesion portion 54 is provided on the facing surface 523, adhesion between the facing surface 523 and the sealing body 30 is enhanced. Therefore, tension due to resin shrinkage becomes strong at the exposed surface 611, which is at a position facing the facing surface 523, and tensile stress tends to concentrate on the triple junction 100. On the other hand, in the present embodiment, the low adhesion portion 55 is provided on the facing surface 523, and the high adhesion portion 54 is provided so as to sandwich the facing surface 523 from both sides. According to this, tension due to resin shrinkage becomes weak at the exposed surface 611, and concentration of tensile stress on the triple junction 100 is suppressed.

### Second Embodiment

Hereinafter, other embodiments will be described. Other embodiments will be described focusing on points different from the first embodiment. Hereinafter, also in other embodiments, points different from the previously described embodiments will be mainly described. Configurations, operations, and effects not particularly described in other embodiments are the same as those in the previously described embodiments.

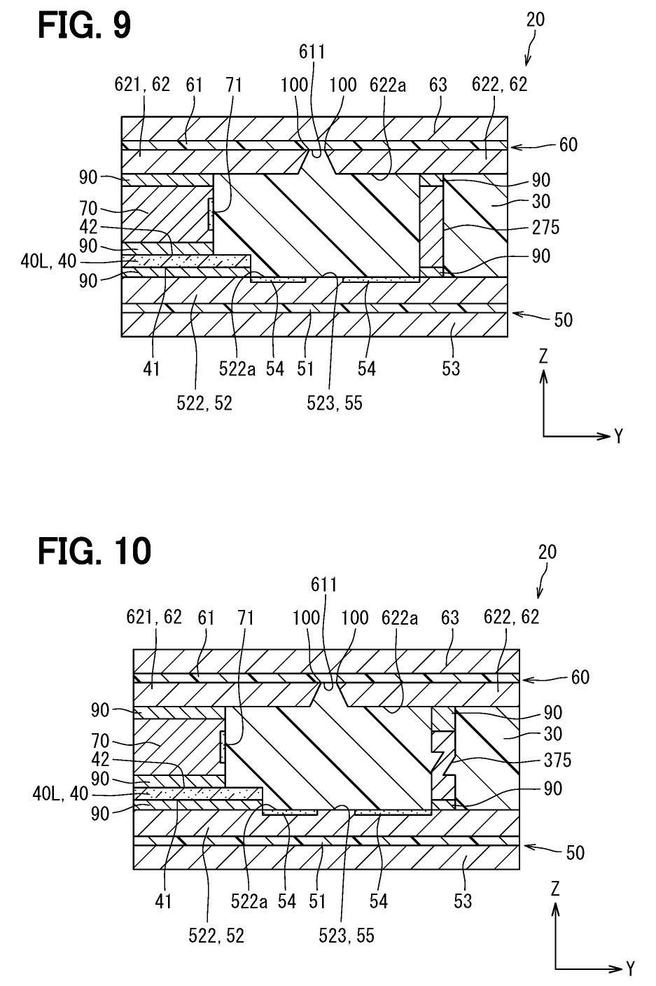

As shown in FIG. 9, in the second embodiment, a joint portion 275 has a columnar shape extending in the Z direction. Materials of the joint portion 275 and the spacer 70 are different in the second embodiment. The joint portion 275 contains aluminum as a material. Aluminum has properties of smaller Young's modulus and yield point than copper. Also in the second embodiment, in the elastic region and the plastic region, the joint portion 275 is more easily deformed than the spacer 70. The joint portion 275 contains a material that is more easily deformed than the spacer 70. This also produces the same effects as in the first embodiment. Note that the shape of the joint portion 275 is not limited to the columnar shape. The shape of the joint portion 275 may be the same crank shape as in the first embodiment, or various shapes described below.

### Third Embodiment to Ninth Embodiment

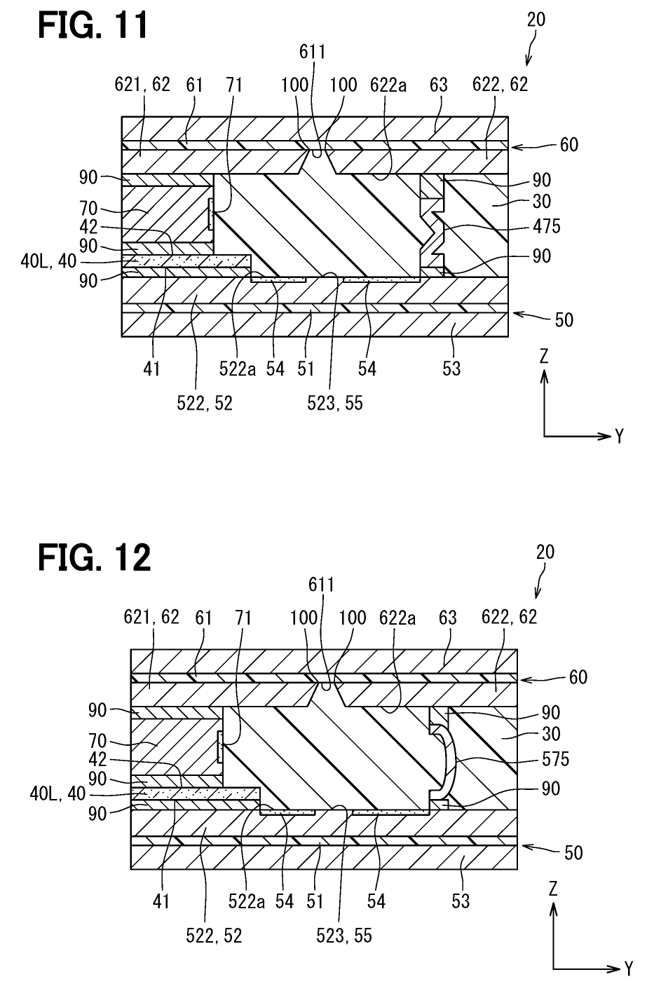

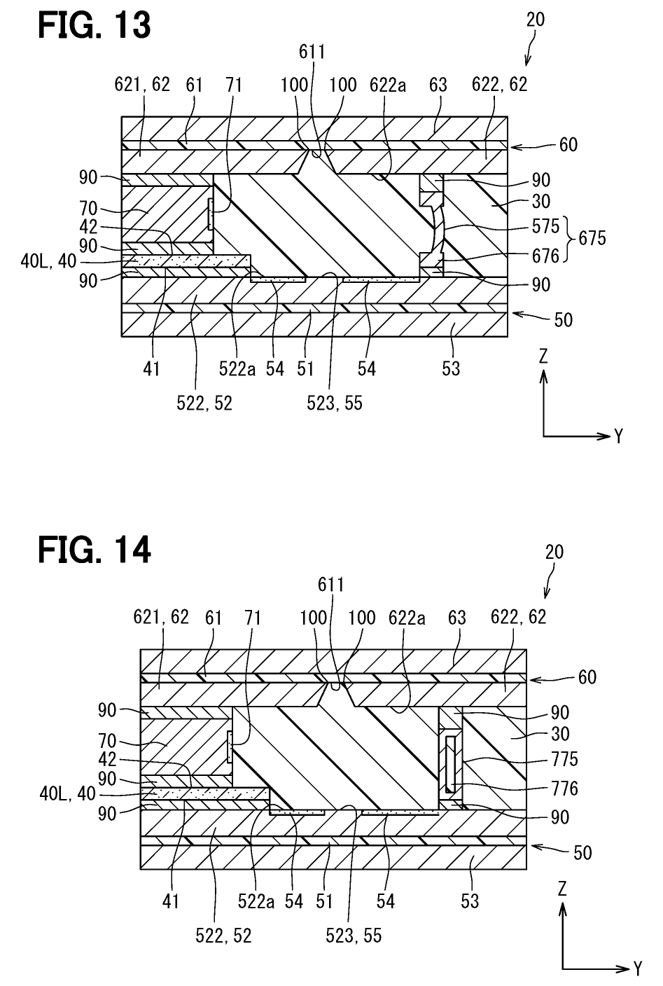

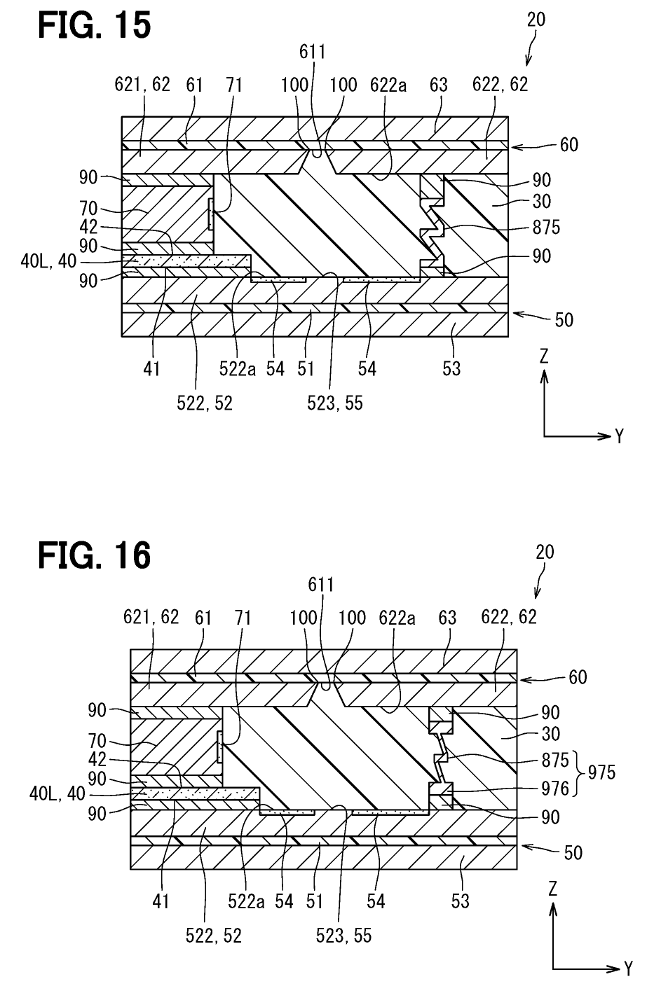

As shown in FIG. 10, in a third embodiment, a joint portion 375 has a Z shape in a cross-sectional view. As shown in FIG. 11, in a fourth embodiment, a joint portion 475 has an M shape in a cross-sectional view. As shown in FIG. 12, in a fifth embodiment, a joint portion 575 has an arc shape bending in the Y direction. As shown in FIG. 13, in a sixth embodiment, a joint portion 675 has a shape obtained by adding extension portions 676 extending in the Y direction to both ends in the Z direction of the joint portion 575 in the fifth embodiment. As shown in FIG. 14, in a seventh embodiment, a joint portion 775 has an annular shape including a through hole 776 penetrating in the X direction. As shown in FIG. 15, in an eighth embodiment, a joint portion 875 has a bellows shape in which mountain folds and valley folds are alternately repeated to be folded in a zigzag manner. As shown in FIG. 16, in a ninth embodiment, a joint portion 975 has a shape obtained by adding extension portions 976 extending in the Y direction to both ends in the Z direction of the joint portion 875 in the eighth embodiment. Also in the third embodiment to the ninth embodiment, the joint portion is more easily deformable than the spacer 70. The joint portion is easier to deform in the Z direction. This produces the same effects as in the first embodiment.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A semiconductor device comprising:
a first substrate and a second substrate facing the first substrate, each of the first substrate and the second substrate including:
an insulating base material,
a front surface metal body disposed on a front surface of the insulating base material, and
a back surface metal body disposed on a back surface of the insulating base material;
a semiconductor element including a first semiconductor element and a second semiconductor element, the first semiconductor element and the second semiconductor element being arranged along a lateral direction, each of the first semiconductor element and the second semiconductor element being electrically connected to the front surface metal body of the first substrate and to the front surface metal body of the second substrate;
a joint portion electrically connecting the front surface metal body of the first substrate and the front surface metal body of the second substrate;
at least one spacer disposed between at least one of the first semiconductor element or the second semiconductor element and the second substrate in a thickness direction of the at least one of the first semiconductor element or the second semiconductor element, the at least one spacer providing a current conduction path between the at least one of the first semiconductor element or the second semiconductor element and the front surface metal body of the second substrate; and
a sealing body sealing the first substrate, the second substrate, the first semiconductor element, the second semiconductor element, the joint portion, and the at least one spacer, wherein
the insulating base material of at least one of the first substrate or the second substrate has an exposed surface that is exposed from the front surface metal body of the at least one of the first substrate or the second substrate at a position between the at least one spacer and the joint portion in the lateral direction and is in contact with the sealing body, and
the joint portion is configured to be more easily deformable than the at least one spacer.

2. The semiconductor device according to claim 1, wherein
a Young's modulus of the joint portion is smaller than a Young's modulus of the at least one spacer.

3. The semiconductor device according to claim 1, wherein
a yield point of the joint portion is smaller than a yield point of the at least one spacer.

4. The semiconductor device according to claim 1, wherein
the front surface metal body facing the exposed surface of the at least one of the first substrate or the second substrate in the thickness direction has a high adhesion portion and a low adhesion portion,
the high adhesion portion has adhesion to the sealing body,
the low adhesion portion has lower adhesion to the sealing body than that of the high adhesion portion,
the low adhesion portion overlaps with the exposed surface in the thickness direction, and
the high adhesion portion is disposed on opposite sides of the low adhesion portion in the lateral direction.

5. The semiconductor device according to claim 1, wherein
the joint portion has a structure configured to deform in the thickness direction.

6. The semiconductor device according to claim 1, wherein
the joint portion contains aluminum, and the at least one spacer contains copper.
